(19) United States
(12) Patent Application Publication
(10) Pub. No.: US 2008/0073746 A1
(43) Pub. Date: Mar. 27, 2008

(54) Semiconductor device

(75) Inventor: Hiroyuki Tanaka, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/892,729

(22) Filed: Aug. 27, 2007

(30) Foreign Application Priority Data
Sep. 27, 2006 (JP) 2006-262373

(51) Int. Cl. H01L 29/00; H01L 21/3205

(52) U.S. Cl. 257/510; 438/591; 257/E21.294; 257/E29.001

(57) ABSTRACT

According to the present invention, there is provided a semiconductor device having a gate field plate structure, which includes a semiconductor substrate; a gate insulation film formed on the semiconductor substrate; a protective insulation film formed on the semiconductor substrate; a gate electrode formed on the gate insulation film; and a field plate electrode of the same electric potential as that of the gate electrode, formed on the protective insulation film. The protective insulation film is formed on the surface of the semiconductor substrate, and is not formed inside the substrate.

### CROSS REFERENCE TO RELATED APPLICATION

This application claims the priority of Application No. 2006-262373, filed Sep. 27, 2006 in Japan, the subject matter of which is incorporated herein by reference.

### TECHNICAL FIELD OF THE INVENTION

The present invention relates to a semiconductor device which employs a gate field plate structure, and a method of manufacturing the same.

### BACKGROUND OF THE INVENTION

In a MOS (Metal-Oxide Semiconductor) device, as a means to secure the withstand voltage between source and drain, a gate field plate structure is employed, for example as shown in the following Non Patent Document 1. The gate field plate structure is formed so that the end of a gate electrode lies on a field oxide film formed usually by the LOCOS method, thereby distributing the electric field at the moment of gate-off and securing the withstand voltage. In general, it is applied to a lateral MOS device having withstand voltage approximately over 20V.

### [Non Patent Document 1]

A. Kitamura, et al. “self-Isolated and High Performance Complementary Lateral DMOSFETs with Surrounding-Body Regions” Proceedings of ISPSD, p. 42 (1995)

In FIG. 4, a lateral double-diffused MOS (LDMOS) structure which is a semiconductor device according to the conventional art is shown. Also, in FIG. 4, a field oxide film 22 as an isolation region is formed on a silicon substrate 10 using the LOCOS method. On the silicon substrate 10, a gate electrode 26 is formed via a gate oxide film 24. This gate electrode 26 lies on the field oxide film 22. In addition, the reference number 28 denotes a body region; 30a and 30b denote source drain regions; 32 denotes a drawer region from the body region; 34 denotes a silicone oxide film; 36 denotes a contact; and 38 denotes an aluminum wiring layer.

However, in the semiconductor device of the configuration shown above, since the field oxide film on which the gate electrode lies is formed simultaneously with other field oxide films used for isolation, various problems have occurred.

The field oxide film 22 on which a part of the gate electrode lies has a film thickness for example approximately 600 nm in the same manner as other field oxide films (isolation region) 22. Of this thickness, approximately 300 nm is formed below the surface of the silicon substrate 10. For this reason, when source and the body region 28 are grounded, and a positive voltage is applied to the drain region, in the field oxide film end A (portion enclosed with circle of dashed line in the figure) which contacts the silicon substrate 10, the concentration of the electric field easily takes place, which causes a decline of the withstand voltage.

### OBJECTS OF THE INVENTION

The present invention has been made in consideration of the above-mentioned circumstances, and an object of the present invention is to provide a semiconductor device which is able to control the concentration of the electric field in the insulation film under a field plate electrode.

Further, another object of the present invention is to provide a method of manufacturing a semiconductor device which is able to control the concentration of the electric field in the insulation film under the field plate electrode.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to the present invention, the end shape of the insulation film under the field plate electrode is moderately inclined. Here, the field plate structure is a structure where a field plate electrode of the same electric potential as that of the gate electrode is formed on the protective film between the gate electrode and the drain electrode of a transistor, and thereby reducing the concentration of the electric field in the gate electrode end during the operation and obtaining high withstand voltage, and high output.

According to a first aspect of the present invention, there is provided a semiconductor device having a gate field plate structure, which includes a semiconductor substrate; a gate insulation film formed on the semiconductor substrate; a protective insulation film formed on the semiconductor substrate; a gate electrode formed on the gate insulation film; and a field plate electrode of the same electric potential as that of the gate electrode, formed on the protective insulation film. The protective insulation film is formed on the surface of the semiconductor substrate, and is not formed inside the substrate.

It is preferable to form the protective insulation film by high-density plasma CVD method or isotropic wet etching method.

According to a second aspect of the present invention, there is provided a semiconductor device which is formed in a region isolated by an isolation region using the LOCOS method, and includes a semiconductor substrate; a gate insulation film formed on the semiconductor substrate; a protective insulation film formed on the semiconductor substrate using the LOCOS method; a gate electrode formed on the gate insulation film; and a field plate electrode of the same electric potential as that of the gate electrode, formed on the protective insulation film. The protective insulation film is formed thinner than the isolation region.

According to a third aspect of the present invention, there is provided a method of manufacturing a semiconductor device having a gate field plate structure, which includes a step of forming a protective insulation film on a semiconductor substrate by high-density plasma CVD method; a step of forming a gate insulation film on the semiconductor substrate, and a step of forming a gate electrode on the gate insulation film and the protective insulation film.

According to a fourth aspect of the present invention, there is provide a method of manufacturing a semiconductor device having a gate field plate structure, which includes a step of forming a protective insulation film on a semiconductor substrate by isotropic wet etching method; a step of forming a gate insulation film on the semiconductor substrate; and a step of forming a gate electrode on the gate insulation film and the protective insulation film.

According to a fifth aspect of the present invention, there is provided a method of manufacturing a semiconductor device having a gate field plate structure, which includes a step of forming an isolation region and a protective insulation film on a semiconductor substrate using the LOCOS method; a step of forming a gate insulation film on the semiconductor substrate; and a step of forming a gate electrode on the gate insulation film and the protective insulation film. The protective insulation film is formed thinner than the isolation region.

According to the present invention, it is possible to form the end shape of the insulation film under the field plate electrode moderately inclined, and control the concentration of the electric field generated at the end of the insulation film under the field plate electrode effectively. As a result, it is possible to restrain the withstand voltage decline of a semiconductor device.

The protective insulation film under the gate field plate is not formed inside the silicon substrate, and accordingly the flatness of the silicon substrate surface is maintained. Further, the protective insulation film has a moderate inclination at the end thereof, and the protective film thickness under the gate electrode does not change sharply. Furthermore, it is possible to determine the film thickness of the protective insulation film independently from the field oxide film thickness for isolation, and distribute the electric field under the best conditions. As a result, it becomes possible to prevent such a withstand voltage decline by the concentration of the electric field in the oxide film end as seen in the conventional art.

When the isotropic wet etching method is employed for forming the protective insulation film on the semiconductor substrate, there is no necessity of using the silicone epitaxial growth method and the high-density plasma CVD method, and accordingly it is possible to form the protective insulation film at low cost.

On the other hand, according to the second and the fifth aspects of the present invention mentioned above, the protective insulation film is formed by the LOCOS method in the same manner as the isolation region, and the protective insulation film is thinner in thickness, and the shape of bird's beak becomes moderate. Therefore, the flatness of the semiconductor substrate surface is maintained more than in the conventional art, and it becomes possible to prevent the withstand voltage decline by the concentration of the electric field at the end of the protective insulation film. Moreover, it becomes possible to form field oxide films which have different film thickness values by one photolithography process, and restrain the increase of manufacturing cost.

In the method of manufacturing a semiconductor device according to the third aspect, preferably, in the process of the high-density plasma CVD method, the ratio (A:B) of the deposition power (A) working onto the plasma processing chamber to the sputtering power (B) working onto the substrate to be processed is set to approximately 4:3.

In the method of manufacturing a semiconductor device according to the third aspect, the step of forming the protective insulation film may include a step of forming slots in other region than the region where the protective insulation film is formed on the semiconductor substrate; a step of forming an insulation film on the semiconductor substrate by high-density plasma CVD method after forming the slots; a step of removing the insulation film formed in the slots; and a step of forming a semiconductor layer of the same concentration and of the same conductivity type as those of semiconductor substrate inside the slots and flattening the semiconductor substrate.

In the method of manufacturing a semiconductor device according to the fifth aspect, preferably, the thickness of the protective insulation film is half or below the thickness of the isolation region.

In the method of manufacturing a semiconductor device according to the fifth aspect, the step of forming the isolation region and the protective insulation film may include a step of patterning a silicone nitride film on the semiconductor substrate; and a step of thermally oxidizing the semiconductor substrate by using the silicone nitride film as a mask. Further, the silicone nitride film is so patterned as to partially cover the semiconductor substrate, in the region where the protective insulation film is formed.

In the method of manufacturing a semiconductor device according to the fifth aspect, preferably, the silicone nitride film is so patterned that the slots are formed at regular intervals, in the region the protective insulation film is formed.

### BRIEF DESCRIPTION OF THE DRAWINGS

FIGS. 1A-1N are cross sectional views each showing a part of the method of manufacturing a semiconductor device according to a first embodiment of the present invention.

FIGS. 2A-2J are cross sectional views each showing a part of the method of manufacturing a semiconductor device according to a second embodiment of the present invention.

FIGS. 3A-3I are cross sectional views each showing a part of the method of manufacturing a semiconductor device according to a third embodiment of the present invention.

FIG. 4 is a cross sectional view showing the structure of a semiconductor device according to the conventional art.

### DESCRIPTION OF REFERENCE NUMBERS

110, 210, 310: Silicon Substrate
114: Slot
116a, 212a: Silicone Oxide Film (protective insulation film)
122, 222, 322:LOCOS oxide film (isolation region)
124, 224, 324: Gate Oxide Film
126, 226, 326: Gate Electrode
322a: LOCOS Oxide Film (protective insulation film)

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

### First Embodiment

A semiconductor device according to a first embodiment of the present invention has a gate field plate structure. As explained later herein, a silicone oxide film (protective insulation) on which a part of a gate electrode lies is formed by other method than the LOCOS oxidizing method, and the flatness of a silicon substrate surface is maintained. Furthermore, it is characterized by that the inclination of the end of the silicone oxide film (protective insulation film) is moderate, and the oxide film thickness under the gate electrode does not change sharply.

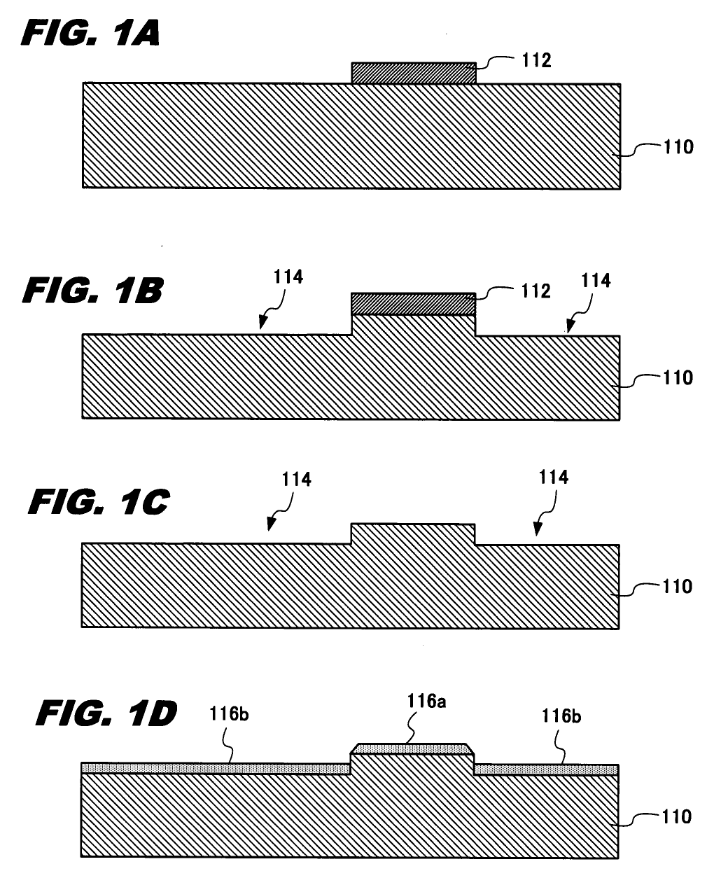

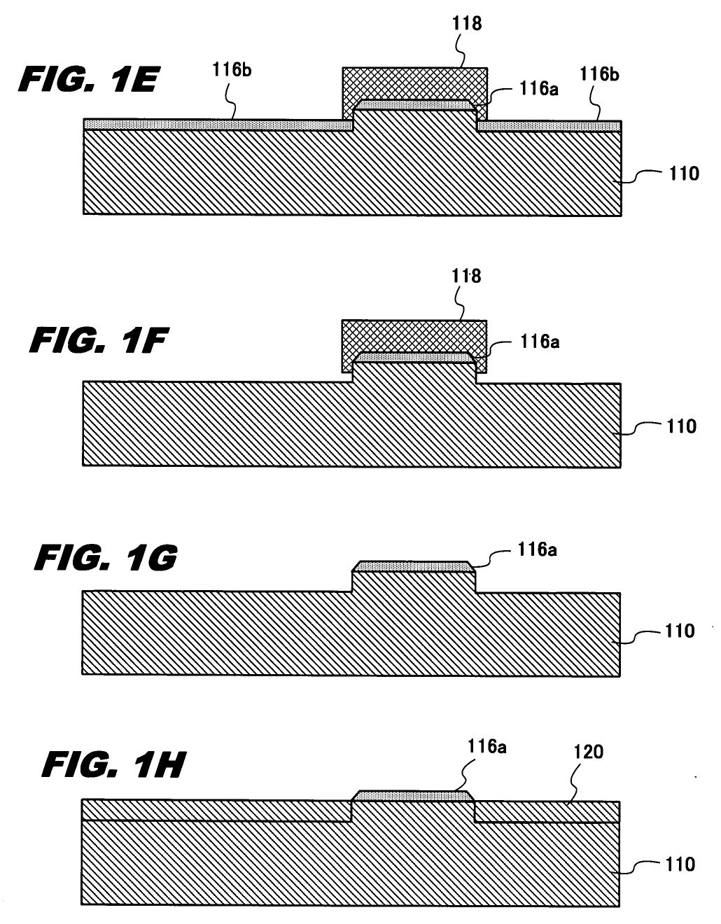

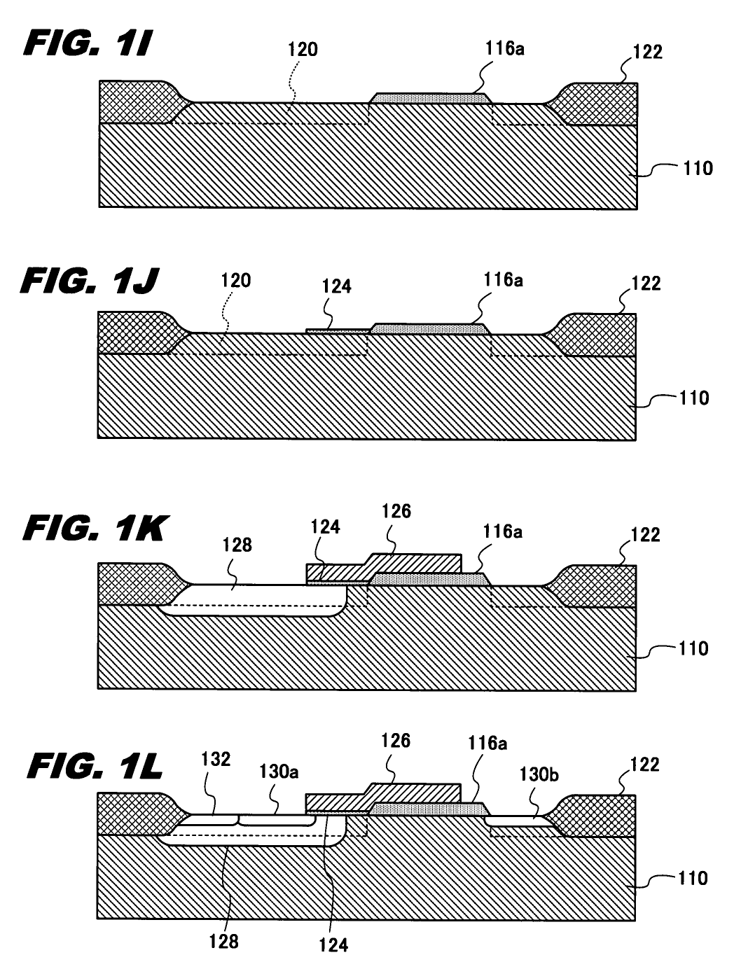

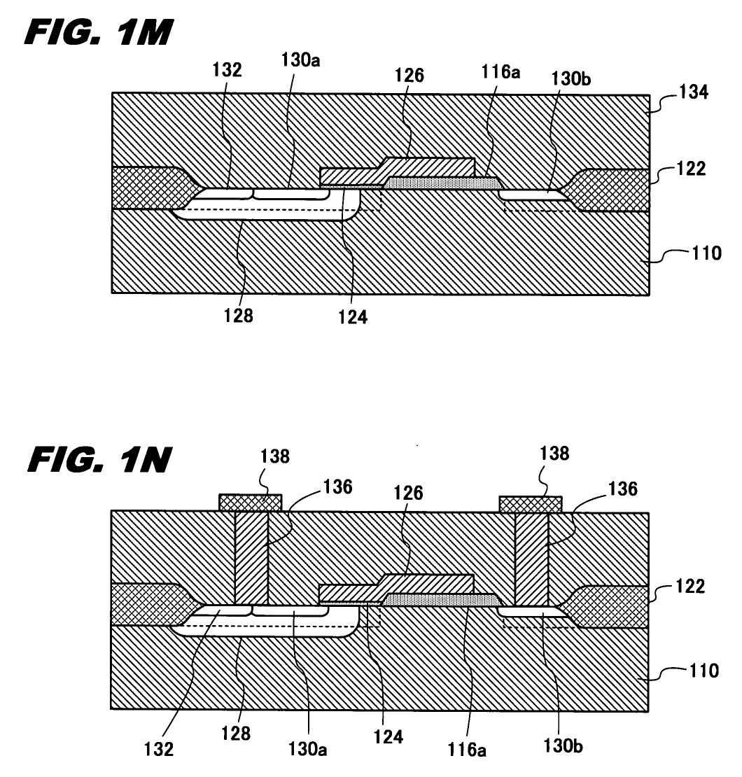

FIGS. 1A-1N are cross sectional views each showing a method of manufacturing a LDMOS (lateral diffused MOS) to become a semiconductor device according to the first embodiment of the present invention.

First, as shown in FIG. 1A, a photo resist 112 is patterned on an N type silicon substrate 10 by photolithography techniques.

Next, as shown in FIG. 1B, by etching with the photo resist 112 as a mask, slots (steps) 114 of depth of approximately 500 nm are formed in the N type silicone substrate 10. The formation position of the slots 114 is the region of the circumference which regulates the region to form a protective insulation film.

Then, as shown in FIG. 1C, the photo resist 112 on the silicone substrate 10 is removed.

Next, as shown in FIG. 1D, silicone oxide films (116a, 116b) are deposited approximately 300 nm on the entire surface of a silicone substrate 110 by high-density plasma CVD method. At this moment, the silicone oxidize film 116a is formed on the surface of the silicone substrate 110 on which the slots 114 are not formed, in the state where the deposition angle of the end is kept at approximately 60 degrees (to the upright). Moreover, separately from the silicone oxide film 116a, the silicone oxide film 116b is formed on the bottom of the slots 114.

In the high-density plasma CVD process, for example, it is preferable that the ratio (A:B) of the deposition power (A=4 kW) working on a plasma processing chamber side to the sputtering power (B=3 kW) working on the substrate to be processed is set to approximately 4:3. Moreover, it is preferable that the substrate temperature is approximately 700 degrees C.

Next, as shown in FIG. 1E, a photo resist 118 is formed by the photolithography method so as to cover the silicone oxide film 116a.

Next, as shown in FIG. 1F, the silicone oxide film 116b at the bottom of the slots 114 is removed by using the photo resist 118 as a mask.

Then, as shown in FIG. 1G, the photo resist 118 on the silicone oxide film 116a is removed. In addition, in the formation process of the silicone oxide films (116a, 116b) shown in FIG. 1D, when the usual plasma CVD with low density is employed, the silicone oxide films 116a and 116b are connected, and a silicone oxide film is formed also on the side surface of a step part. Consequently, even after the photo resist 118 is removed, there occurs a nonconformity that the silicone oxide film is left on the side surface of the step part.

Next, as shown in FIG. 1H, silicone 120 of the same concentration as that of the silicone substrate 110 is made to grow up to the surface of the silicone substrate 110 by the epitaxial method, and the surface of the silicone substrate 110 is flattened.

Next, as shown in FIG. 1I, a field oxide film 122 for isolation is formed approximately 600nm in film thickness on the silicone substrate 110 using the usual LOCOS method.

Next, as shown in FIG. 1J, a gate oxide film 124 is formed 20 nm in film thickness on the silicone substrate 110 by the thermal oxidation method.

Next, after multicrystalline silicone including phosphorous as an impurity is deposited 300 nm in film thickness on the silicone substrate 110, by the photolithography etching method, as shown in FIG. 1K, a gate electrode 126 is formed. The gate electrode 126 is formed not only on the gate oxide film 124 but on the silicone oxide film (protective insulation film) 112a, thereby forming a gate field plate structure.

Next, by photolithography ion implantation technique, boron is implanted into a desired region of the silicone substrate 110, and is spread and activated by heat treatment at 1100° C. (degrees C) for approximately 60 minutes, thereby forming a body region 128 shown in FIG. 1K.

Furthermore, by employing the photolithography ion implantation technique twice, arsenic and boron are implanted into a desired region of the silicone substrate 110, and are activated by subsequent heat treatment at 900° C. (degrees C) for approximately 30 minute, and as shown in FIG. 1L, source drain regions 130a and 130b and, a drawer region 132 from the body region 128 are formed.

Next, as shown in FIG. 1M, a silicone oxide films 134 is deposited approximately 1 μm on the entire surface by the CVD method, and is flattened.

Then as shown in FIG. 1N, a contact 136 connected to the source drain regions 130a and 130b is formed in the silicone oxide film 134 by the usual method. Moreover, an aluminum wiring layer 138 to be connected with the contact 136 on the surface of the silicone oxide film 134 is formed.

The operation of the semiconductor device according to the present embodiment is same as that of a LDMOS having the usual gate field plate structure. That is, the source and the body region 128 are grounded and a voltage of the threshold value or higher is applied to the gate electrode 126 while a positive voltage of withstand voltage or lower is applied to the drain region. As a result, the body layer surface is reversed and a channel is formed, and the current flows from the drain to the source. By repeatedly applying such a voltage to the gate electrode 126, the LDMOS performs a switching operation. At the moment of gate-off, the electric field can be distributed by the gate field plate structure and the withstand voltage can be secured.

As explained above, according to the first embodiment, the oxide film 116a under the gate field plate (126) is not formed inside the silicone substrate 110, and the flatness of the silicone substrate 110 surface is maintained. Moreover, this oxide film 116a has a moderate inclination of the end thereof, and the thickness thereof does not change sharply. Furthermore, it is possible to determine the film thickness of the silicone oxide film 116a as a protective insulation film independently from the film thickness of the field oxide film 122 for isolation. For this reason, it is possible to distribute the electric field under the best conditions and consequently, it becomes possible to prevent such a withstand voltage decline by the concentration of the electric field in the oxide film end as seen in the conventional art.

### Second Embodiment

A semiconductor device according to a second embodiment of the present invention has a gate field plate structure in the same manner as the first embodiment mentioned above. As explained later herein, a silicone oxide film (protective insulation) on which a part of a gate electrode lies is formed by other method than the LOCOS oxidizing method, and the flatness of a silicon substrate surface is maintained. Furthermore, it is characterized by that the inclination of the end of the silicone oxide film (protective insulation film) is moderate, and the oxide film thickness under the gate electrode does not change sharply.

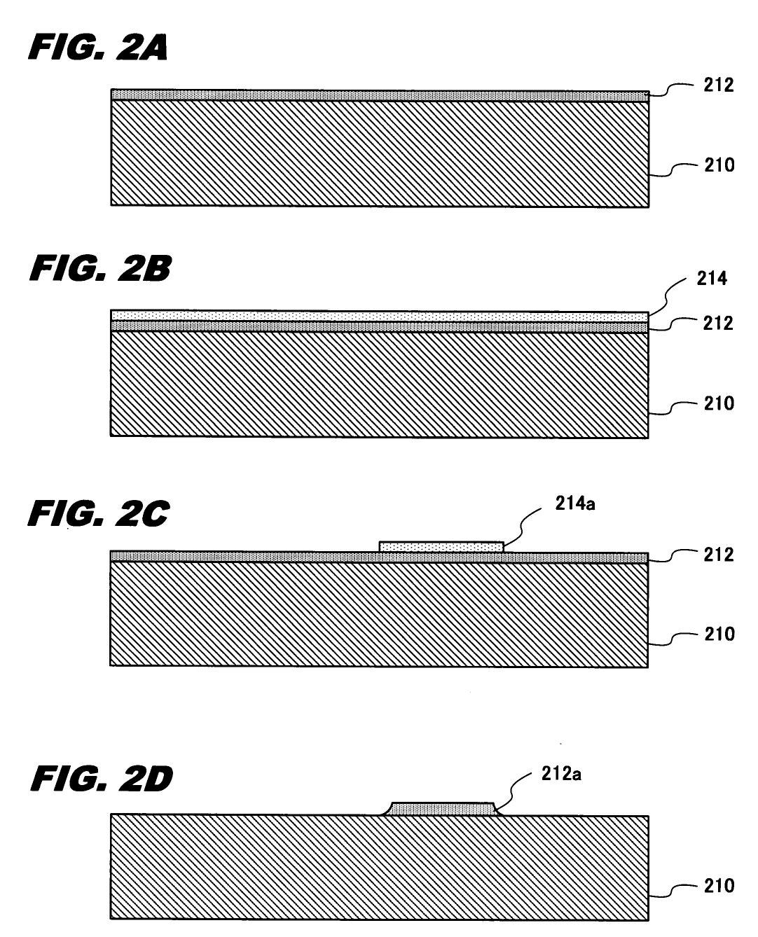

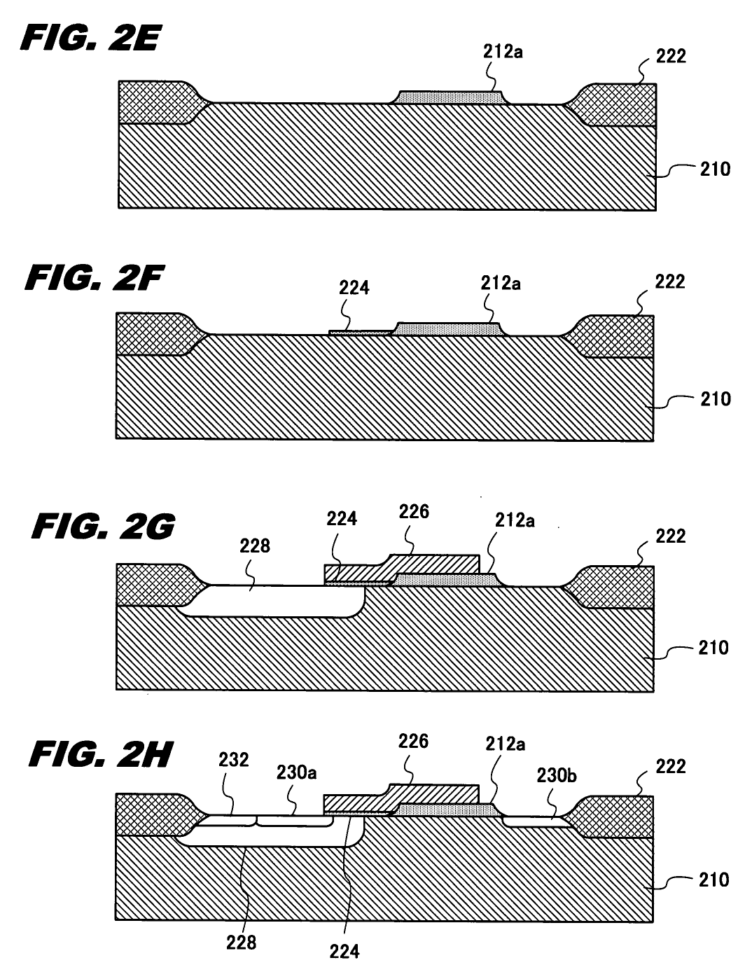

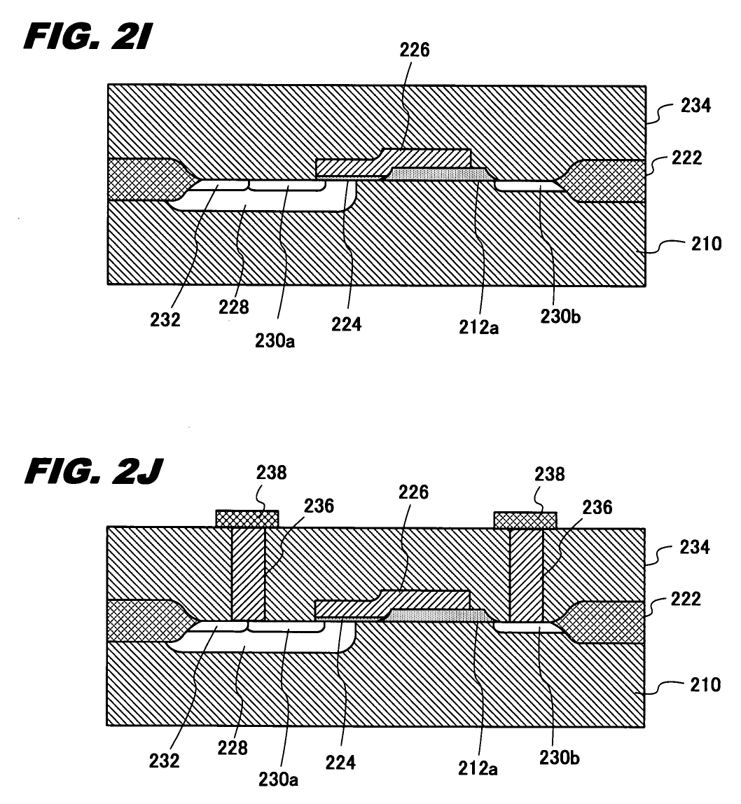

FIGS. 2A-2J are cross sectional views each showing a method of manufacturing a LDMOS (lateral diffused MOS) to become a semiconductor device according to the second embodiment of the present invention.

First, as shown in FIG. 2A, a silicone oxide film 212 of film thickness 300 nm is formed on an N type silicon substrate 210 by the CVD method.

Next, as shown in FIG. 2B, a silicone nitride film 214 of film thickness 300nm is formed on the silicone oxide film 212 by the CVD method.

Next, by photolithography and etching processing, as shown in FIG. 2C, the silicone nitride film 214 in the region equivalent to a protective insulation film (oxide film under a gate field plate) is left as a mask 214a.

Next, by using the left silicone nitride film 214a as a mask, the silicone oxide film 212 is removed isotropically by wet etching method. By isotropic etching, the end of the silicone oxide film 212 has a shape curving inward, as shown in FIG. 2D.

Next, as shown in FIG. 2E, a field oxide film 222 for isolation of film thickness approximately 600 nm is formed on the silicon substrate 210, by the usual LOCOS method.

Next, as shown in FIG. 2F, a gate oxide film 224 of film thickness 20 nm is formed on the silicon substrate 210 by the thermal oxidation method.

Next, after multicrystalline silicone including phosphorous as an impurity is deposited 300 nm in film thickness on the silicone substrate 210, by the photolithography etching method, as shown in FIG. 2G, a gate electrode 226 is formed. The gate electrode 226 is formed not only on the gate oxide film 224 but on the silicone oxide film (protective insulation film) 212a, thereby forming a gate field plate structure.

Next, by photolithography ion implantation technique, boron is implanted into a desired region of the silicone substrate 210, and is spread and activated by heat treatment at 1100° C. for approximately 60 minutes, thereby forming a body region 228 shown in FIG. 2G.

Furthermore, by employing the photolithography ion implantation technique twice, arsenic and boron are implanted into a desired region of the silicone substrate 210, and are activated by subsequent heat treatment at 900° C. for approximately 30 minutes, and as shown in FIG. 2H, source drain regions 230a and 230b, and a drawer region 232 from the body region 228 are formed.

Next, as shown in FIG. 7(I), a silicone oxide film 234 is deposited approximately 1 μm on the entire surface by the CVD method, and is flattened.

Then, as shown in FIG. 2J, a contact 236 connected to the source drain regions 230a and 230b is formed in the silicone oxide film 234 by the usual method. Moreover, an aluminum wiring layer 238 to be connected with the contact 236 on the surface of the silicone oxide film 234 is formed.

The operation of the semiconductor device according to the present embodiment is same as that of the first embodiment mentioned above. That is, the source and the body region 228 are grounded and a voltage of the threshold value or higher is applied to the gate electrode 226 while a positive voltage of withstand voltage or lower is applied to the drain region. As a result, the body layer surface is reversed and a channel is formed, and the current flows from the drain to the source. By repeatedly applying such a voltage to the gate electrode 226, the LDMOS performs a switching operation. At the moment of gate-off, the electric field can be distributed by the gate field plate structure and the withstand voltage can be secured.

As explained above, according to the second embodiment, the oxide film 212a under the gate field plate (226) is not formed inside the silicon substrate 210, and the flatness of the silicon substrate 210 surface is maintained. Moreover, this oxide film 212a has a moderate inclination of the end thereof, and the thickness thereof does not change sharply. Furthermore, it is possible to determine the film thickness of the silicone oxide film 212a as a protective insulation film independently from the film thickness of the field oxide film 122 for isolation. For this reason, it is possible to distribute the electric field under the best conditions and consequently, it becomes possible to prevent such a withstand voltage decline by the concentration of the electric field in the oxide film end as seen in the conventional art.

In addition, according to the second embodiment of the present invention, there is no necessity of using the silicone epitaxial growth method and the high-density plasma CVD method for forming the protective oxide film (212a). Therefore, it is possible to manufacture the semiconductor device at lower cost than in the first embodiment.

### Third Embodiment

A semiconductor device according to a third embodiment of the present invention has a gate field plate structure in the same manner as the first and second embodiments mentioned above. As explained later herein, a silicone oxide film on which a part of a gate electrode lies is formed by the LOCOS oxidizing method, but the film thickness thereof is thinner than that of other field oxide film for isolation. For this reason, the flatness of the silicon substrate surface is maintained well in comparison with the conventional art structure. Furthermore, it is characterized by that the inclination of the end of the silicone oxide film (protective insulation film) is moderate, and the oxide film thickness under the gate electrode does not change sharply.

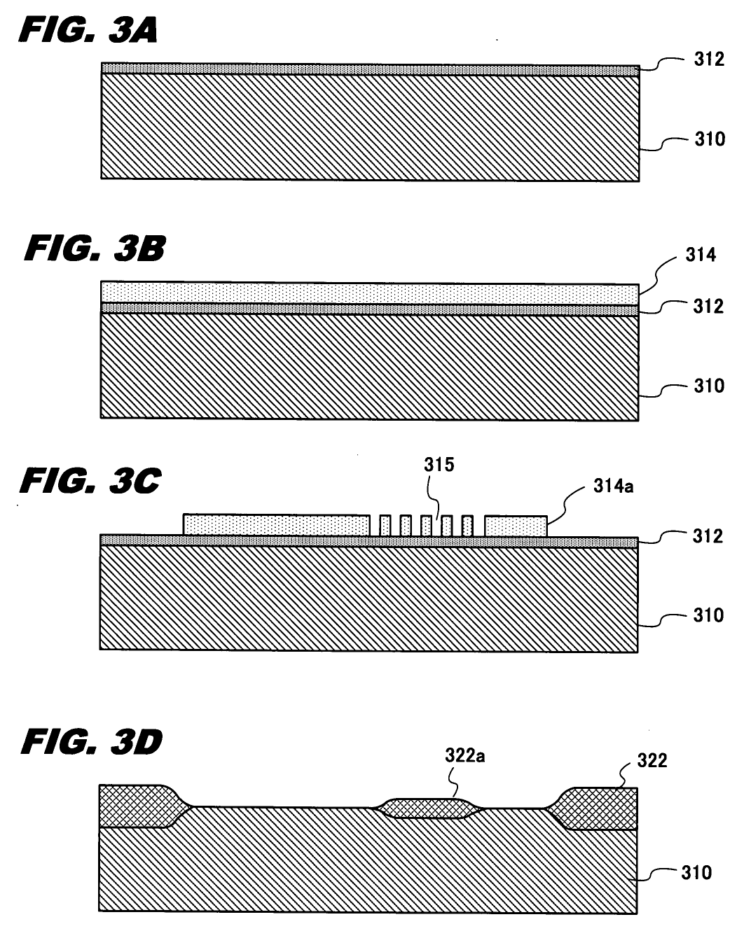

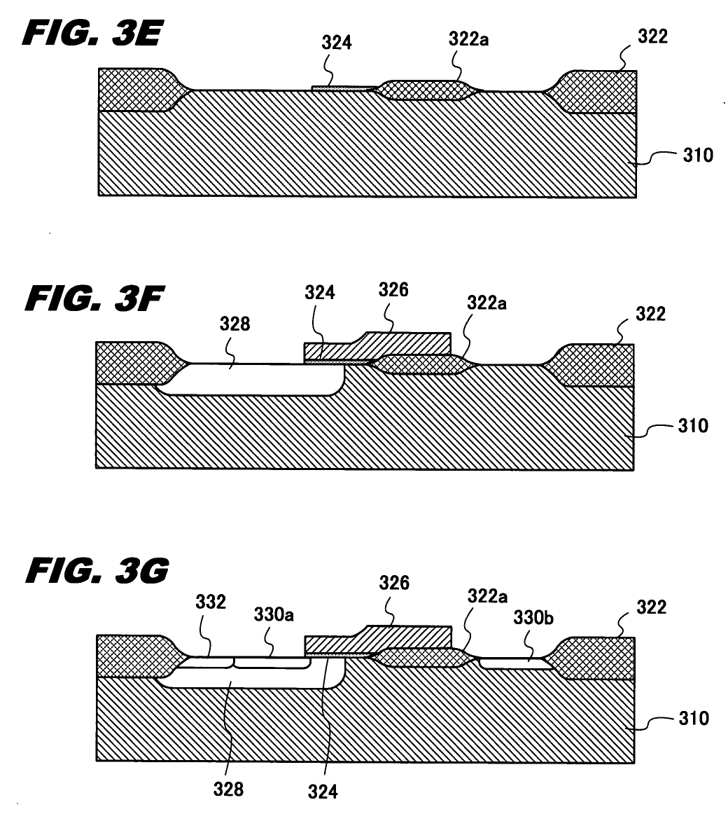

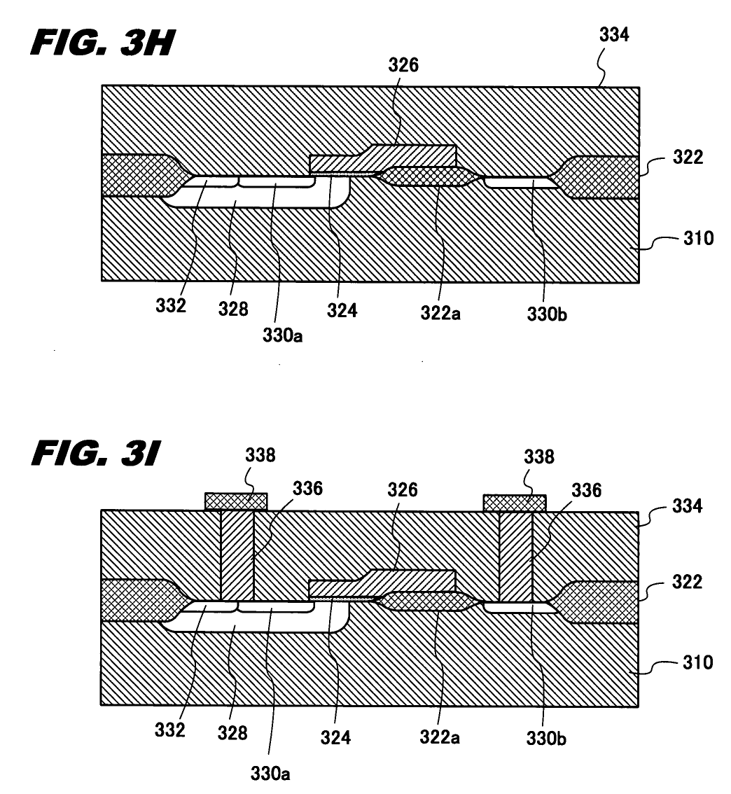

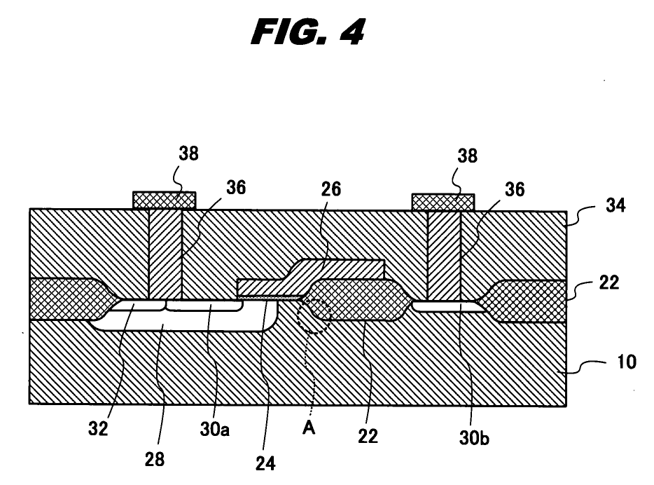

FIGS. 3A-3I are cross sectional views each showing a method of manufacturing a LDMOS (lateral diffused MOS) to become a semiconductor device according to the third embodiment of the present invention.

First, as shown in FIG. 3A, a silicone oxide film 312 of film thickness 50nm is formed on an N type silicon substrate 310 by the thermal oxidation method.

Next, as shown in FIG. 3B, a silicone nitride film 314 of film thickness 200 nm is formed on the silicone oxide film 312 by the CVD method.

Next, as shown in FIG. 3C, by the photolithography etching method, the silicone nitride film 314 in the region which finally becomes a field oxide film is removed, and a mask pattern 314a is formed. At this point, in the region where the silicone oxide film under the gate field plate is formed, slots 315 are formed in line and space of 0.2 μm width. In addition, the slots 315 may employ other shapes such as dots, matrices and so on, in place of line and space.

Next, by the thermal oxidation method at 1000° C., the exposed silicon substrate surface is oxidized and a thick field oxide film 322 of film thickness approximately 600 nm is formed using the silicone nitride film 314a as a mask. At this point, the region between the slots 315 is also oxidized to some extent, thereby forming, in the region in which the gate field plate is formed, a thin field oxide film 322a of film thickness approximately 300 nm. Then, as shown in FIG. 3D, the silicone nitride film 314 and the silicone oxide film 312 are removed from the silicon substrate 310 by the etching method.

Next, as shown in FIG. 3E, a gate oxide film 324 of film thickness 20 nm is formed on the silicon substrate 310 by the thermal oxidation method.

Next, after multicrystalline silicone including phosphorous as an impurity is deposited 300 nm in film thickness on the silicone substrate 310, by the photolithography etching method, as shown in FIG. 3F, a gate electrode 326 is formed. The gate electrode 326 is formed not only on the gate oxide film 324 but on the silicone oxide film (protective insulation film) 332a, thereby forming a gate field plate structure.

Next, by photolithography ion implantation technique, boron is implanted into a desired region of the silicone substrate 310, and is spread and activated by heat treatment at 1100° C. for approximately 60 minutes, thereby forming a body region 328 shown in FIG. 3F.

Furthermore, by employing the photolithography ion implantation technique twice, arsenic and boron are implanted into a desired region, and are activated by subsequent heat treatment at 900° C. for approximately 30 minutes, and as shown in FIG. 3G, source drain regions 330a and 330b, and a drawer region 332 from the body region 328 are formed.

Next, as shown in FIG. 3H, a silicone oxide films 334 is deposited approximately 1 μm on the entire surface by the CVD method, and is flattened.

Then, as shown in FIG. 31, a contact 336 connected to the source drain regions 330a and 330b is formed in the silicone oxide film 334 by the usual method. Moreover, an aluminum wiring layer 338 to be connected with the contact 336 on the surface of the silicone oxide film 334 is formed.

The operation of the semiconductor device according to the present embodiment is same as that of the first and second embodiments mentioned above. That is, the source and the body region 328 are grounded and a voltage of the threshold value or higher is applied to the gate electrode 326 while a positive voltage of withstand voltage or lower is applied to the drain region. As a result, the body layer surface is reversed and a channel is formed, and the current flows from the drain to the source. By repeatedly applying such a voltage to the gate electrode 326, the LDMOS performs a switching operation. At the moment of gate-off, the electric field can be distributed by the gate field plate structure and the withstand voltage can be secured.

As mentioned above, according to the third embodiment of the present invention, the protective insulation film under the gate field plate is formed by the LOCOS method in the same manner as in the isolation region, and the protective insulation film is thinner in thickness, and the shape of bird's beak becomes moderate. As a result, the flatness of the semiconductor substrate surface is maintained more than in the conventional art, and it becomes possible to prevent the withstand voltage decline by the concentration of the electric field at the end of the protective insulation film.

Moreover, it becomes possible to form field oxide films (322, 322a) which have different film thickness values by one photolithography process, and consequently it is possible to restrain the increase of manufacturing cost.

What is claimed is:

1. A semiconductor device with a gate field plate structure, comprising:
a semiconductor substrate;
a gate insulation film formed on siad semiconductor substrate;
a protective insulation film formed on said semiconductor substrate;
a gate electrode formed on said gate insulation film; and
a field plate electrode of the same electric potential as that of said gate electrode, formed on said protective insulation film, wherein
said protective insulation film is formed on the surface of said semiconductor substrate, and is not formed inside the substrate.

2. A semiconductor device according to claim 1, wherein
said gate electrode and said field plate electrode are formed in an integrated manner.

3. A semiconductor device according to claim 1, wherein
said protective insulation film is formed by high-density plasma CVD method.

4. A semiconductor device according to claim 2, wherein
said protective insulation film is formed by high-density plasma CVD method.

5. A semiconductor device according to claim 1, wherein
said protective insulation film is formed by isotropic wet etching method.

6. A semiconductor device according to claim 2, wherein
said protective insulation film is formed by isotropic wet etching method.

7. A semiconductor device with a gate field plate structure, formed in a region isolated by an isolation region using the LOCOS method, comprising:
a semiconductor substrate;
a gate insulation film formed on said semiconductor substrate;
a protective insulation film formed on said semiconductor substrate using the LOCOS method;
a gate electrode formed on said gate insulation film; and
a field plate electrode of the same electric potential as that of said gate electrode, formed on said protective insulation film, wherein
said protective insulation film is formed thinner than said isolation region.

8. A semiconductor device according to claim 7, wherein
the thickness of said protective insulation film is half or below the thickness of said isolation region.
